(19) United States
(12) Patent Application Publication
(10) Pub. No.: US 2025/0142817 A1
(43) Pub. Date: May 1, 2025

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Kuan Dong, Wuhan (CN); Gang Zhang, Wuhan (CN); Meng Xiao, Wuhan (CN); Longdong Liu, Wuhan (CN); Zhou He, Wuhan (CN); Pan Wang, Wuhan (CN); Jin Dong, Wuhan (CN); Meng Xiao, Wuhan (CN); Liheng Liu, Wuhan (CN)

(21) Appl. No.: 18/387,777

(22) Filed: Nov. 7, 2023

(30) Foreign Application Priority Data
Nov. 1, 2023 (CN) 202311452138.0

(51) Int. Cl. H10B 41/27; G11C 16/04; H10B 41/10; H10B 41/35; H10B 43/10; H10B 43/27; H10B 43/35

(52) U.S. Cl. CPC H10B 41/27; G11C 16/0483; H10B 41/10; H10B 41/35; H10B 43/10; H10B 43/27; H10B 43/35

(57) ABSTRACT

Implementations of three-dimensional (3D) memory devices and fabricating methods thereof are disclosed. In some implementations, the disclosed 3D memory device comprises: a stack structure including a plurality of dielectric layers and conductive layers alternatively stacked in a vertical direction; an array of channel structures each vertically penetrating the stack structure, each channel structure including a functional layer and a channel layer; and a plurality of isolation structures extending in parallel along a first lateral direction and vertically in an upper portion of the stack structure, each isolation structure being in contact with the channel layers of two adjacent rows of channel structures.

### CROSS-REFERENCE TO RELATED APPLICATIONS

This application claims the benefit of priority to Chinese Application No. 202311452138.0, filed on Nov. 1, 2023, which is incorporated herein by reference in its entirety.

### TECHNICAL FIELD

The present disclosure generally relates to the field of semiconductor technology, and more particularly, to three-dimensional (3D) memory devices, and fabricating methods for forming three-dimensional (3D) memory devices.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As such, memory density for planar memory cells approaches an upper limit. A three-dimensional (3D) memory architecture can address the density limitation in planar memory cells.

As semiconductor technology advances, 3D memory devices, such as 3D NAND memory devices, keep reducing costs and increasing capacity. The density of memory cells in the horizontal plane continues to be compressed. The top select gates (TSGs) are necessary structures for NAND memory devices. Since TSG cuts are required between memory strings, the storage unit density of NAND memory devices can be greatly reduced.

### BRIEF SUMMARY

Implementations of three-dimensional (3D) memory devices and fabricating methods thereof are disclosed herein.

One aspect of the present disclosure provides a semiconductor structure, comprising: a stack structure including a plurality of dielectric layers and conductive layers alternatively stacked in a vertical direction; an array of channel structures each vertically penetrating the stack structure, each channel structure including a functional layer and a channel layer; and a plurality of isolation structures extending in parallel along a first lateral direction and vertically in an upper portion of the stack structure, each isolation structure being in contact with the channel layers of two adjacent rows of channel structures.

In some implementations, each isolation structure partially covers the two adjacent rows of channel structures in a lower portion of the stack structure.

In some implementations, the plurality of isolation structures comprises: a plurality of first isolation structures each separating the conductive layers of the upper portion of the stack structure into sub-blocks.

In some implementations, the isolation structure is in contact with curved side surfaces of the channel layers of the two adjacent rows of channel structures in the upper portion of the stack structure.

In some implementations, the isolation structure is in contact with filling structures of the two adjacent rows of channel structures in the upper portion of the stack structure.

In some implementations, a column of channel structures extending along a second lateral direction and located on a same side of the first isolation structures are connected to a common bit line.

In some implementations, the plurality of isolation structures further comprises: a plurality of second isolation structures each extending along the first lateral direction without separating the conductive layers of the upper portion of the stack structure; wherein the plurality of first and second isolation structures are alternatively arranged along a second lateral direction.

In some implementations, the plurality of second isolation structures each including a plurality of second isolation segments discontinuously extended along the first lateral direction.

In some implementations, a first subset of a column of channel structures extending along a second lateral direction and in contact with the first isolation structures are connected to a first common bit line; and a second subset of the column of channel structures in contact with the second isolation structures are connected to a second common bit line.

In some implementations, the array of channel structures comprises: dummy channel structures in contact with corners of the second isolation segments.

In some implementations, the semiconductor structure further comprises: a plurality of gate line structures extending in parallel along the first lateral direction and vertically penetrating the stack structure; wherein a first number of the isolation structures between adjacent gate line structures plus one is a half of a second number of the rows of channel structures between the adjacent gate line structure.

In some implementations, a lateral cross section of the functional layer of the channel structure in the upper portion of the stack structure has a partial ring shape; and two lateral ends of the partial ring-shaped functional layer are in contact with the isolation structure.

In some implementations, a lateral cross section of the channel layer of the channel structure in the upper portion of the stack structure has a partial ring shape; and two lateral ends of the partial ring-shaped channel layer are in contact with the isolation structure.

In some implementations, the partial ring shape is larger than a one third ring.

In some implementations, a depth of the isolation structure is greater than a total thickness of one top pair of the dielectric layers and the conductive layers, and less than a total thickness of seven top pairs of the dielectric layers and the conductive layers.

Another aspect of the present disclosure provides a method of forming a semiconductor structure, comprising: forming a dielectric stack structure; forming an array of channel structures each vertically penetrating the dielectric stack structure, each channel structure including a functional layer and a channel layer; transforming the dielectric stack structure into a stack structure including a plurality of alternatively stacked dielectric layers and conductive layers; removing portions of the channel structures and the stack structure in an upper portion of the stack structure to form a plurality of trenches extending in parallel along a first lateral direction, each trench exposes the channel layers of two adjacent rows of channel structures in the upper portion of the stack structure; and forming a plurality of isolation structures in the trenches each in contact with the channel layers of two adjacent rows of channel structures.

In some implementations, each isolation structure is formed to partially cover the two adjacent rows of channel structures in a lower portion of the stack structure.

In some implementations, forming the plurality of trenches comprises: removing portions of the functional layer of the channel structures in the upper portion of the stack structure.

In some implementations, forming the plurality of trenches further comprises: removing portions of the channel layers of the channel structures in the upper portion of the stack structure.

In some implementations, forming the plurality of isolation structures comprises: forming the plurality of isolation structures in the trenches, each isolation structure being in contact with curved side surfaces of the channel layers of the two adjacent rows of channel structures in the upper portion of the stack structure.

In some implementations, forming the plurality of isolation structures comprises: forming the plurality of isolation structures in the trenches, each isolation structure being in contact with filling structures of the two adjacent rows of channel structures in the upper portion of the stack structure.

In some implementations, forming the plurality of trenches comprises: forming a plurality of first trenches each separating the conductive layers of the upper portion of the stack structure into sub-blocks.

In some implementations, the method further comprises: forming a plurality of bit lines extending in parallel along a second lateral direction, each bit line is connected to a column of channel structures extending along the second lateral direction and located on a same side of the isolation structures.

In some implementations, the method further comprises: forming a plurality of second trenches each extending along the first lateral direction without separating the conductive layers of the upper portion of the stack structure; and forming a plurality of second isolation structures in the second trenches, wherein the plurality of first and second isolation structures are alternatively arranged along a second lateral direction.

In some implementations, forming the plurality of second trenches comprises forming a plurality of second trench segments discontinuously extended along the first lateral direction; forming the plurality of second isolation structures comprises forming a plurality of second isolation segments in the plurality of second trench segments.

In some implementations, the method further comprises: forming dummy channel structures in contact with corners of the second isolation segments.

In some implementations, the method further comprises: forming the dielectric stack structure comprises forming a plurality of dielectric layers and sacrificial layers alternatively stacked in a vertical direction; transforming the dielectric stack structure into a stack structure comprises: forming a plurality of gate line structures extending in parallel along the first lateral direction and vertically penetrating the dielectric stack structure, and replacing the sacrificial layers with conductive layers; wherein a first number of the isolation structures between adjacent gate line structures plus one is equal to a second number of the rows of channel structures between the adjacent gate line structure.

Another aspect of the present disclosure provides a semiconductor device, comprising: a plurality of isolation structures extending in parallel along a first lateral direction and vertically in an upper portion of a stack structure; and an array of channel structures each vertically penetrating the stack structure and comprising: a lower channel portion having a cylinder shape in a lower portion of the stack structure, and an upper channel portion having a partial cylinder shape in the upper portion of the stack structure and being in contact with a corresponding isolation structure.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic diagram of a portion of a 3D memory device in an enlarged top-down view, according to some implementations of the present disclosure.

FIG. 2 illustrates a schematic diagram of a portion of a 3D memory device in an enlarged top-down view, according to some implementations of the present disclosure.

FIG. 3 illustrates a schematic diagram of a portion of a 3D memory device in an enlarged top-down view, according to some implementations of the present disclosure.

FIG. 4 illustrates a schematic diagram of a portion of a 3D memory device in an enlarged top-down view, according to some implementations of the present disclosure.

FIG. 5 illustrates a schematic diagram of a portion of a 3D memory device 600 in an enlarged top-down view, according to some implementations of the present disclosure.

FIG. 6 illustrates a schematic diagram of a 3D memory device in a cross-sectional side view, according to some implementations of the present disclosure.

FIG. 7 illustrates a schematic diagram of a portion of a 3D memory device 600 in an enlarged top-down view, according to some implementations of the present disclosure.

FIG. 8 illustrates a schematic diagram of a 3D memory device in a cross-sectional side view, according to some implementations of the present disclosure.

FIG. 9 illustrates a block diagram of a system having a memory device, according to some aspects of the present disclosure.

FIG. 10A illustrates a diagram of an exemplary memory card having a memory device, in accordance with some embodiments.

FIG. 10B illustrates a diagram of an exemplary solid-state drive (SSD) having a memory in accordance with some embodiments.

FIG. 11 illustrates a flow diagram of a method for forming a 3D memory device is shown in accordance with some implementations of the present disclosure.

FIGS. 12-18 illustrate schematics of a 3D memory device at certain fabricating stages of the method shown in FIG. 11 in a cross-sectional view according to various implementations of the present disclosure.

FIG. 19 illustrates a top-down view of a 3D memory device, according to some implementations of the present disclosure.

FIG. 20 illustrates a perspective view of a portion of a 3D memory array structure, according to some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to effect such feature, structure or characteristic in connection with other implementations whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of an Homogeneous or inhomogeneous continuous structure that has a thickness less than the thickness of the continuous structure. For example, a layer can be located between any pair of lateral planes between, or at, a top surface and a bottom surface of the continuous structure. A layer can extend laterally, vertically, and/or along a tapered surface. A substrate can be a layer, can include one or more layers therein, and/or can have one or more layer thereupon, thereabove, and/or therebelow. A layer can include multiple layers. For example, an interconnection layer can include one or more conductor and contact layers (in which contacts, interconnect lines, and/or vias are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “3D memory device” refers to a semiconductor device with vertically-oriented strings of memory cell transistors (i.e., region herein as “memory strings,” such as NAND strings) on a laterally-oriented substrate so that the memory strings extend in the vertical direction with respect to the substrate. As used herein, the term “vertical/vertically” means nominally perpendicular to a lateral surface of a substrate.

As described above, 3D NAND memory devices keep reducing costs and increasing capacity by compressing the density of memory cells in the horizontal plane. However, the top select gate (TSG) structures, as necessary structures for NAND memory devices, located between memory strings, have a negative impact of the storage unit density of NAND memory devices. Specifically, one approach of TSG structures includes using stacks of multiple rows of channel structures, arranging a row of dummy channel structures between every four rows of channel structures, and separating stacks of gate layers to form TSG structures. The first approach has a low cost and a simple fabricating process but has a high loss of die per wafer (DPW). Another approach of TSG structures includes adding an additional TSG deck on the upper layer of the channel structures and interconnected with the channel structures through a small-aperture TSG channel. The limited space due to the small aperture allows wave-shaped TSG structures to save area in the horizontal plane. However, the second approach has a high cost and complex fabricating process. Further, the structures generally use four rows of channel structures as a group, and each bit line and/or TSG in the same group controls two channel structures. Such arrangement may cause crosstalk during programming and reading, which is harmful to the reliability of the 3D NAND memory devices.

Accordingly, various implementations in accordance with the present disclosure provide 3D memory devices and fabricating methods thereof to address the above issues. Specifically, in some implementations, two rows of channel structures can be used as a group. As such, the bit line connection does not require a double pattern but can be realized by a single patten. That is, one layer of TSG structure plus one bit line can control a single row of channel structure, thereby reducing disturbance during programming and reading and reducing metal wiring. Further, in some implementations, the channel structures corresponding to TSG structures can be designed to have a partial circular shape. That is, the current switch of the channel structure can be controlled through a partial-circular gate electrode of the TSG. As such, there is no need to design a partition area as the dummy channel structures. The disclosed design of TSG isolation function can be fabricated by simple processes without increasing process costs and/or produce area.

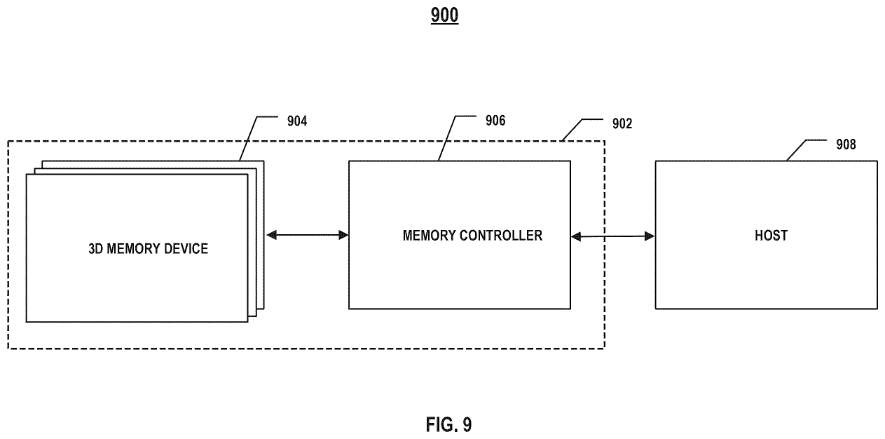

FIG. 9 illustrates a block diagram of a system 900 having a memory device, according to some aspects of the present disclosure. System 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, system 900 can include a host 908 and a memory system 902 having one or more memory devices 904 and a memory controller 906. Host 908 can be a processor of an electronic device, such as a central processing unit (CPU), or a system-on-chip (SoC), such as an application processor (AP). Host 908 can be configured to send or receive the data to or from memory devices 904.

Memory device 904 can be any memory devices disclosed herein, such as a NAND Flash memory device. Consistent with the scope of the present disclosure, memory controller 906 may control the multi-pass programming on memory device 904 such that an NGS operation is enabled on all memory cells, even those passed the respective verify operations, in a non-last programming pass of the multi-pass programming. The peripheral circuits, such as the word line drivers, may apply a low voltage, e.g., ground (GND) voltage, on the DSGs of each memory string coupled to the selected word line, and may apply a low or negative voltage on the selected word line to enable an NGS operation on all memory cells coupled to the selected word line during a non-last programming pass.

Memory controller 906 is coupled to memory device 904 and host 908 and is configured to control memory device 904, according to some implementations. Memory controller 906 can manage the data stored in memory device 904 and communicate with host 908. In some implementations, memory controller 906 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed for operating in a high duty-cycle environment SSDs or embedded multi-media-cards (eMMCs) used as data storage for mobile devices, such as smartphones, tablets, laptop computers, etc., and enterprise storage arrays. Memory controller 906 can be configured to control operations of memory device 904, such as read, erase, and program operations. Memory controller 906 can also be configured to manage various functions with respect to the data stored or to be stored in memory device 904 including, but not limited to bad-block management, garbage collection, logical-to-physical address conversion, wear leveling, etc. In some implementations, memory controller 906 is further configured to process error correction codes (ECCs) with respect to the data read from or written to memory device 904. Any other suitable functions may be performed by memory controller 906 as well, for example, programming memory device 904. Memory controller 906 can communicate with an external device (e.g., host 908) according to a particular communication protocol. For example, memory controller 906 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

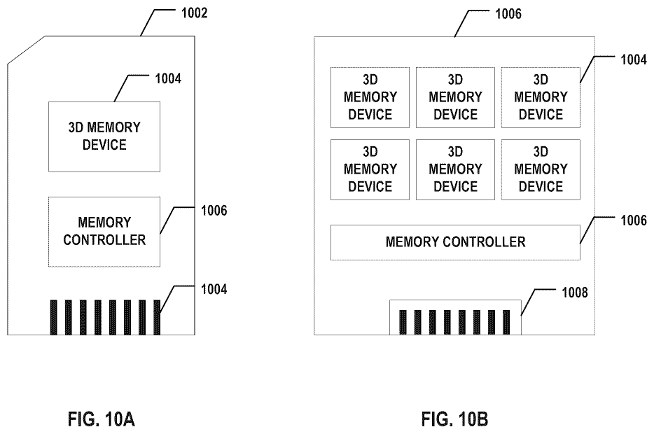

Memory controller 906 and one or more memory devices 904 can be integrated into various types of storage devices, for example, be included in the same package, such as a universal Flash storage (UFS) package or an eMMC package. That is, memory system 902 can be implemented and packaged into different types of end electronic products. In one example as shown in FIG. 10A, memory controller 906 and a single memory device 904 may be integrated into a memory card 1002. Memory card 1002 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1002 can further include a memory card connector 1004 coupling memory card 1002 with a host (e.g., host 908 in FIG. 9). In another example as shown in FIG. 10B, memory controller 906 and multiple memory devices 904 may be integrated into an SSD 1006. SSD 1006 can further include an SSD connector 1008 coupling SSD 1006 with a host (e.g., host 908 in FIG. 9). In some implementations, the storage capacity and/or the operation speed of SSD 1006 is greater than those of memory card 1002.

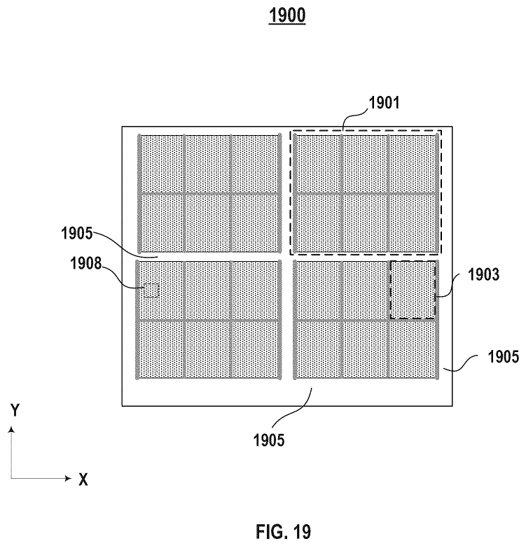

FIG. 19 illustrates a top-down view of a 3D memory device 1900, according to some implementations of the present disclosure. 3D memory device 1900 can be a memory chip (package), a memory chip or any portion of a memory chip, and can include one or more memory planes 1901, each of which can include a plurality of memory blocks 1903. Identical and concurrent operations can take place at each memory plane 1901. Memory block 1903, which can be megabytes (MB) in size, can be the smallest size to carry out erase operations. Shown in FIG. 19, 3D memory device 1900 includes four memory planes 1901 and each memory plane 1901 includes six memory blocks 1903. Each memory block 1903 can include a plurality of memory cells, where each memory cell can be addressed through interconnections such as bit lines and word lines. The bit lines and word lines can be laid out perpendicularly (e.g., in rows and columns, respectively), forming an array of metal lines. In FIG. 19, the direction of word lines is labeled as X-direction, and the direction of bit lines is labeled as Y-direction. In this disclosure, memory block 1903 is also referred to as a “memory array” or “array.” The memory array is the core area in a memory device, performing storage functions.

3D memory device 1900 can include a periphery region 1905, an area surrounding memory planes 1901. Periphery region 1905 can contain many digital, analog, and/or mixed-signal circuits to support functions of the memory array, for example, page buffers, row and column decoders and sense amplifiers. Peripheral circuits use active and/or passive semiconductor devices, such as transistors, diodes, capacitors, resistors, etc., as would be apparent to a person of ordinary skill in the art. It is noted that, the arrangement of memory planes 1901 in 3D memory device 1900 and the arrangement of memory blocks 1903 in each memory plane 1901 illustrated in FIG. 19 are only provided as an example, which does not limit the scope of the present disclosure.

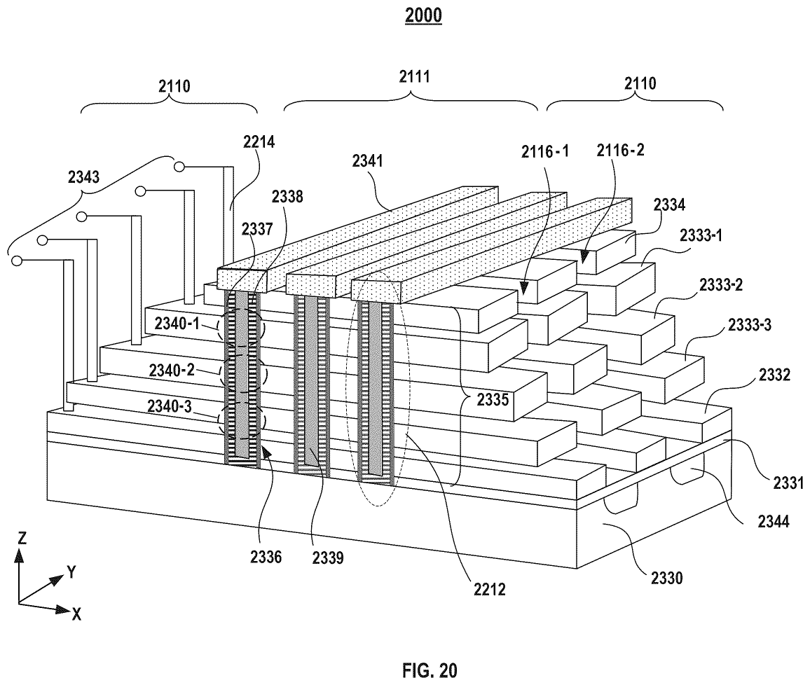

FIG. 20 illustrates a perspective view of a portion of a 3D memory array structure 2000, according to some implementations of the present disclosure. Memory array structure 2000 includes a substrate 2330, an insulating film 2331 over the substrate 2330, one or more tiers of bottom select gates (BSGs) 2332 over the insulating film 2331, and a plurality of tiers of control gates 2333, also referred to as “word lines (WLs),” stacking on top of the BSGs 2332 to form a stack structure 2335 of alternating conductive and dielectric layers. The dielectric layers adjacent to the tiers of control gates are not shown in FIG. 20 for clarity.

The control gates 2333 of each tier are separated by slit structures 2216-1 and 2216-2 through the stack structure 2335. Memory array structure 2000 can include one or more tiers of top select gates (TSGs) 2334 over the stack of control gates 2333. The stack of TSG 2334, control gates 2333 and BSG 2332 are also referred to as “gate structures.” Memory array structure 2000 further includes memory strings 2212 and doped source line regions 344 in portions of substrate 2330 between adjacent BSGs 2332. Each memory strings 2212 includes a channel hole 2336 extending through insulating film 2331 and stack structure 2335 of alternating conductive and dielectric layers. Memory strings 2212 can also include a memory film 2337 (also referred as “functional layer”) on a sidewall of the channel hole 2336, a channel layer 2338 over the memory film 2337, and a core filling film 2339 surrounded by the channel layer 2338. A memory cell 2340 can be formed at the intersection of control gate 2333 and memory string 2212. Memory array structure 2000 further includes a plurality of bit lines (BLs) 2341 connected with memory strings 2212 over TSGs 2334. Memory array structure 2000 can include a plurality of metal interconnect lines 2343 connected with the gate structures through a plurality of contact structures 2214. The edge of stack structure 2335 is configured as a staircase structure to allow an electrical connection to each tier of the gate structures.

In FIG. 20, for illustrative purposes, three tiers of control gates 2333-1, 2333-2, and 2333-3 are shown together with one tier of TSG 2334 and one tier of BSG 2332. In this example, each memory string 2212 can include three memory cells 2340-1, 2340-2 and 2340-3, corresponding to the control gates 2333-1, 2333-2 and 2333-3, respectively. In some implementations, the number of control gates and the number of memory cells can be more than three to increase storage capacity. Memory array structure 2000 can also include other structures, for example, TSG cuts, common source contacts, and dummy channel structures. These structures are not shown in FIG. 20 for simplicity.

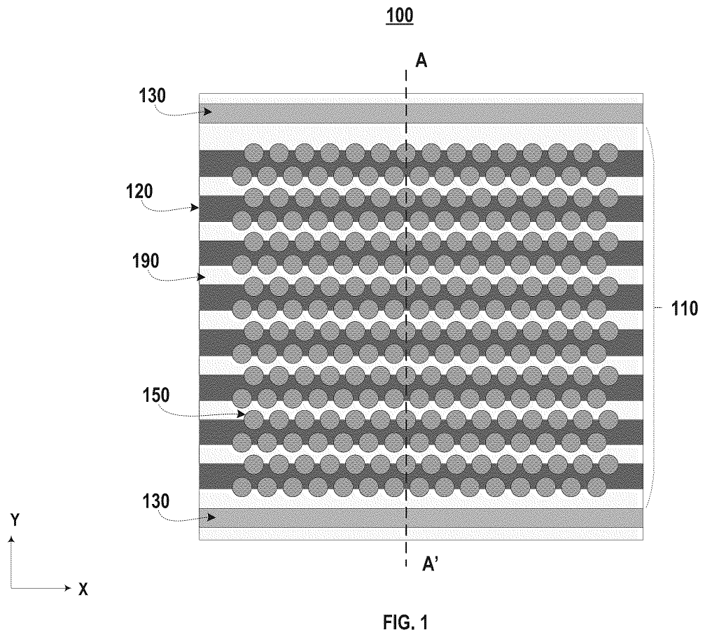

Referring to FIG. 1, a schematic diagram of a portion 100 of 3D memory device, such as region 2008 of FIG. 20 is shown in an enlarged top-down view, according to some implementations of the present disclosure. As shown, multiple slits can be laterally extended in parallel along a word line direction (i.e., X-direction). A gate line slit (GLS) structure 130 can be formed in each slit to divide the memory array into multiple memory fingers 110.

Each memory finger 110 can include an even number (e.g., 8, 16, 32, etc.) of rows of channel structures 150 arranged in a staggered manner between two adjacent GLS structures 130. A plurality of top select gate (TSG) cuts (also referred to as “isolation structures”) 190 can be located between adjacent rows of channel structures 150. The plurality of TSG cuts 190 can laterally extend in parallel along the word line direction (i.e., X-direction) and vertically extend in an upper portion of the stack structure of 3D memory device. Each TSG cut 190 can be in contact with the channel layers of two adjacent rows of channel structures 150. The conductive layers in the upper portion of the stack structure of 3D memory device can be divided by the TSG cuts 190 into a plurality of sub-blocks 120. That is, two adjacent rows of channel structures 150 between two adjacent TSG cuts 190 can share one sub-block 120. In some implementations, a first number of the TSG cuts 190 between adjacent gate line structures 130 plus one is a half of a second number of the rows of channel structures 150 between the adjacent gate line structure 130.

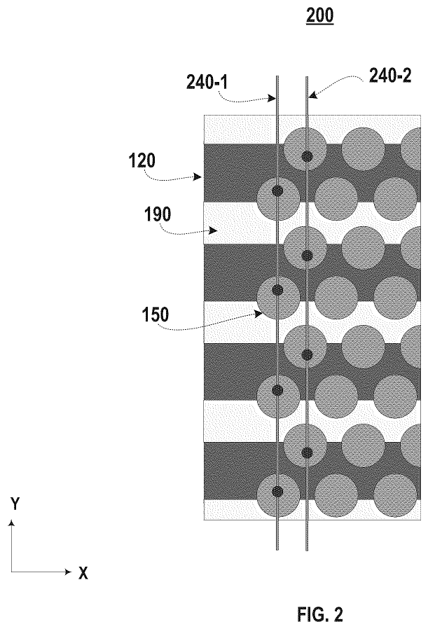

Referring to FIG. 2, a schematic diagram of a portion 200 of the portion 100 of 3D memory device, is shown in an enlarged top-down view, according to some implementations of the present disclosure. As shown, each column of channel structures 150 extending along the bit line direction (i.e., Y-direction) and located on a same side of the TSG cuts 190 can be connected to a common bit line 240. For example, the first column of channel structures 150 that are located on an upper side of the TSG cuts 190 can be connected to a first common bit line 240-1, and the second column of channel structures 150 that are located on a lower side of the TSG cuts 190 can be connected to a second common bit line 240-2.

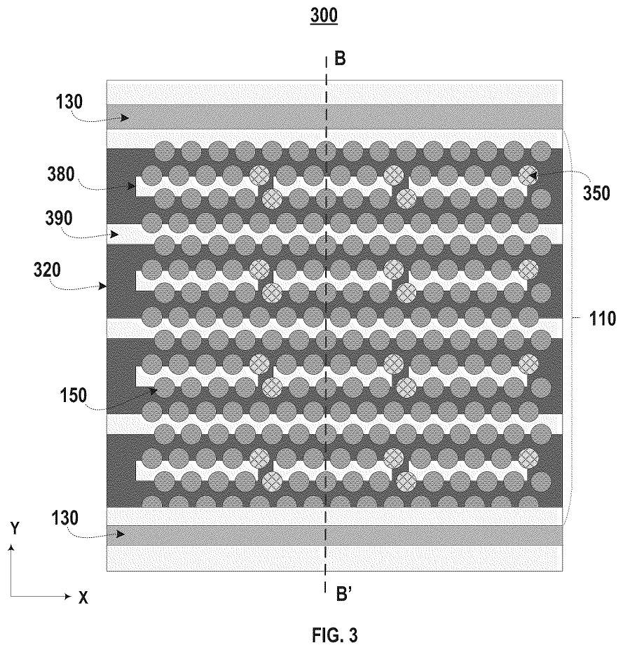

Referring to FIG. 3, a schematic diagram of a portion 300 of 3D memory device, such as region 2008 of FIG. 20 is shown in an enlarged top-down view, according to some other implementations of the present disclosure. As shown, multiple slits can be laterally extended in parallel along a word line direction (i.e., X-direction). A gate line slit (GLS) structure 130 can be formed in each slit to divide the memory array into multiple memory fingers 110.

Each memory finger 110 can include an even number (e.g., 8, 16, 32, etc.) of rows of channel structures 150 arranged in a staggered manner between two adjacent GLS structures 130. A plurality of first top select gate (TSG) cuts (also referred as “first isolation structures”) 390 and second top select gate (TSG) cuts 380 (also referred as “second isolation structures”) can be located between adjacent rows of channel structures 150. The plurality of first TSG cuts 390 and second TSG cuts 380 are alternatively arranged along the bit line direction (i.e., Y-direction). The plurality of first TSG cuts 390 and second TSG cuts 380 can laterally extend in parallel along the word line direction (i.e., X-direction) and vertically extend in an upper portion of the stack structure of 3D memory device. Each second TSG cut 380 can include a plurality of second TSG cut segments (also referred as “second isolation segments”) discontinuously extended along the word line direction (X-direction).

Each first TSG cut 390 or second TSG cut 380 can be in contact with the channel layers of two adjacent rows of channel structures 150. It is noted that, dummy channel structures 350 can be in contact with corners of the second TSG cut segments. The conductive layers in the upper portion of the stack structure of 3D memory device can be divided by the first TSG cuts 390 into a plurality of sub-blocks 320, while the discontinuous second TSG cut segments of the second TSG cuts 380 do not separate the conductive layers. That is, four adjacent rows of channel structures 150 between two adjacent first TSG cuts 390 can share one sub-block 320.

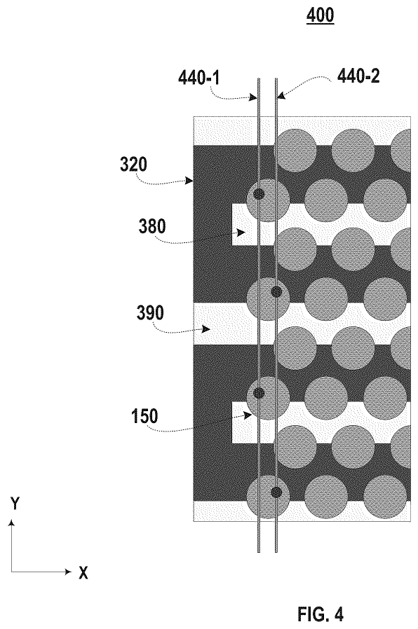

Referring to FIG. 4, a schematic diagram of a portion 400 of the portion 200 of 3D memory device, is shown in an enlarged top-down view, according to some implementations of the present disclosure. In some implementations, a first subset of a column of channel structures extending along a second lateral direction and in contact with the first isolation structures are connected to a first common bit line, and a second subset of the column of channel structures in contact with the second isolation structures are connected to a second common bit line. For example, as shown in FIG. 4, the subset of the first column of channel structures 150 in contact with the second TSG cut structures 380 can be connected to a first common bit line 440-1, and the subset of the first column of channel structures 150 in contact with the first TSG cut structures 380 can be connected to a second common bit line 440-2.

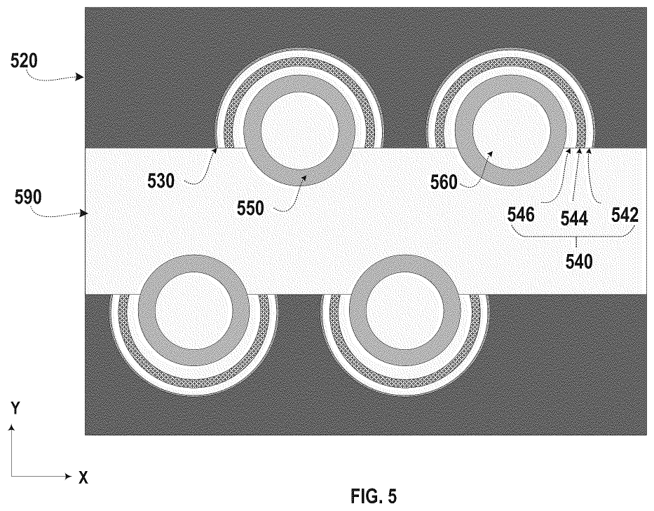

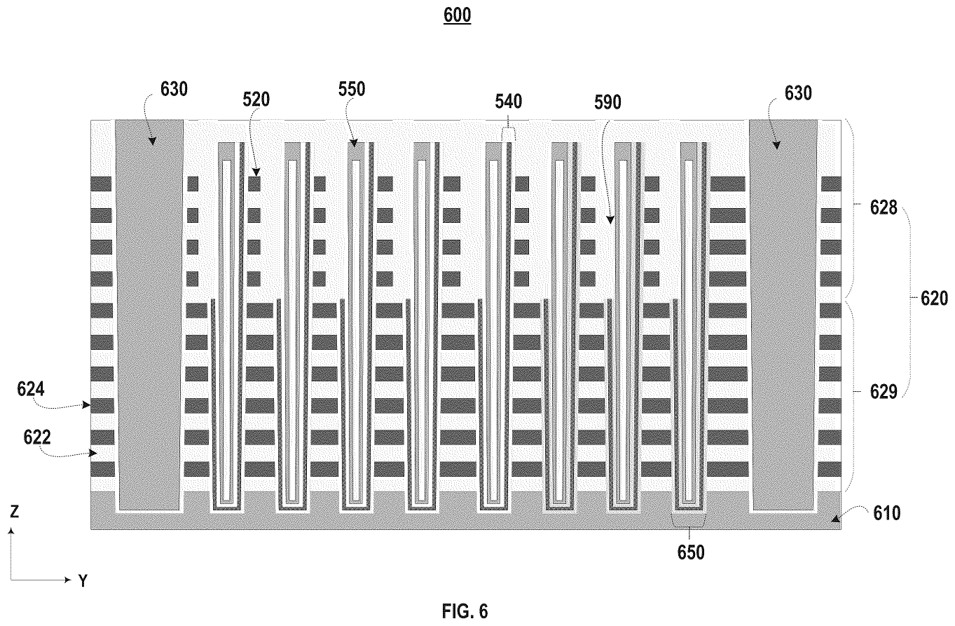

Referring to FIG. 6, a schematic diagram of a 3D memory device 600 is shown in a cross-sectional side view, according to some implementations of the present disclosure. It is noted that, 3D memory device 600 can be along the AA′ line shown in FIG. 1 or along the BB′ line shown in FIG. 3. Referring to FIG. 5, a schematic diagram of a portion 500 of the 3D memory device 600, is shown in an enlarged top-down view, according to some implementations of the present disclosure.

In some implementations, as shown in FIG. 6, stack structure 620 including a plurality of dielectric layers 622 and conductive layers 624 alternatively stacked in a vertical direction can be located on a substrate 610. Gate line slits (GLS) structures 630 can each vertically extend through the stack structure 620 into the substrate 610 and lateral extend along the word line direction (X-direction). Between adjacent GLS structures 630, a plurality of channel structures 650 can each vertically extend through the stack structure 620 into the substrate 610.

As shown in FIGS. 5 and 6, each channel structure 650 can include a high-K dielectric layer 530 on the sidewall of the channel hole, a functional layer (or memory film) 540 covering the high-K dielectric layer 530, a channel layer 550 covering the functional layer 540, and a filling structure 560 encircled by the channel layer 550. In some implementations, the functional layer 540 can include a barrier layer 542, a storage layer 544, and a tunneling layer 546.

As shown in FIGS. 5 and 6, the TSG cuts 590 (e.g., TSG cut structures 190, 390, 380 shown in FIGS. 1-4) can vertically extend in an upper portion 628 of the stack structure 620, and laterally extend along the word line direction (X-direction). Each TSG cut 590 can partially cover the two adjacent rows of channel structures 650 in a lower portion 629 of the stack structure 620. For example, each TSG cut 590 can be located above portions of the functional layer 540 and high-K dielectric layer 530 of the channel structures 650 in the lower portion 629 of the stack structure 620.

As shown in FIG. 5, in the lateral direction, the TSG cut 590 can being in contact with the channel layers 550 of two adjacent rows of channel structures 650. In some implementations, the TSG cut 590 can be in contact with curved side surfaces of the channel layers 550 of the two adjacent rows of channel structures 650 in the upper portion 628 of the stack structure 620. That is, along the word line direction (X-direction), the TSG cut 790 can have concave sidewalls. A lateral cross section of the functional layer 540 of the channel structure 650 in the upper portion 628 of the stack structure 620 can have a partial ring shape. Two lateral ends of the partial ring-shaped functional layer 540 can be in contact with the TSG cut 590. In some implementations, the partial ring shape is larger than a one third ring.

It is noted that, the upper portion 628 of the stack structure 620 can include any suitable number of layers of the dielectric layers 622 and the conductive layers 624. The four top pairs of the dielectric layers 622 and the conductive layers 624 shown in FIG. 6 are merely one example but not limiting the disclosed scope. In some implementations, a depth of the TSG cut 590 is greater than a total thickness of one top pair of the dielectric layers 622 and the conductive layers 624, and less than a total thickness of seven top pairs of the dielectric layers 622 and the conductive layers 624.

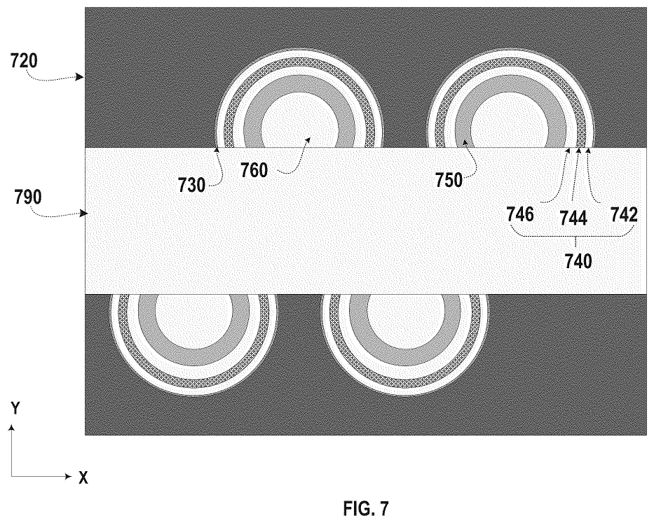

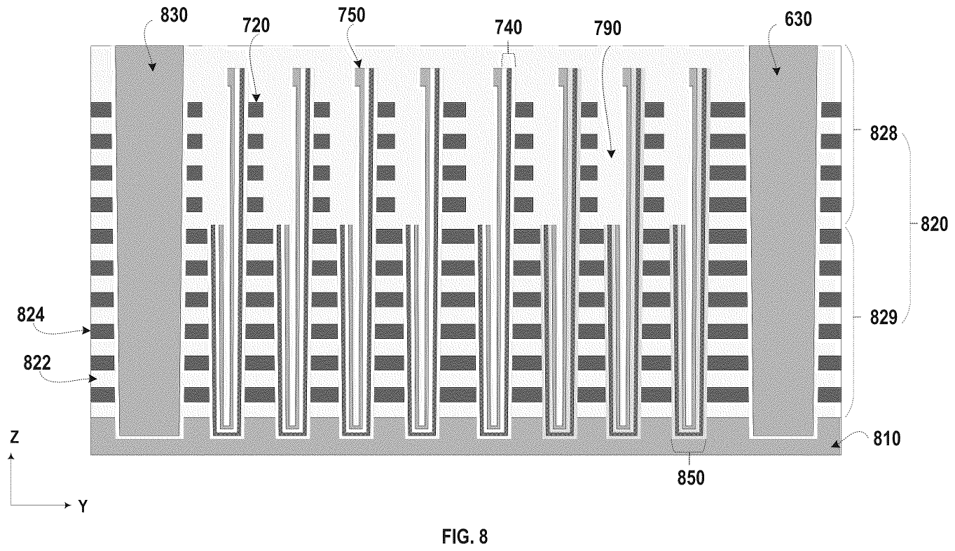

Referring to FIG. 8, a schematic diagram of a 3D memory device 800 is shown in a cross-sectional side view, according to some implementations of the present disclosure. It is noted that, 3D memory device 800 can be along the AA′ line shown in FIG. 1 or along the BB′ line shown in FIG. 3. Referring to FIG. 7, a schematic diagram of a portion 700 of the 3D memory device 800, is shown in an enlarged top-down view, according to some implementations of the present disclosure.

In some implementations, as shown in FIG. 8, stack structure 820 including a plurality of dielectric layers 822 and conductive layers 824 alternatively stacked in a vertical direction can be located on a substrate 810. Gate line slits (GLS) structures 830 can each vertically extend through the stack structure 820 into the substrate 810 and lateral extend along the word line direction (X-direction). Between adjacent GLS structures 830, a plurality of channel structures 850 can each vertically extend through the stack structure 820 into the substrate 810.

As shown in FIGS. 7 and 8, each channel structure 850 can include a high-K dielectric layer 730 on the sidewall of the channel hole, a functional layer (or memory film) 740 covering the high-K dielectric layer 730, a channel layer 750 covering the functional layer 740, and a filling structure 760 encircled by the channel layer 750. In some implementations, the functional layer 740 can include a barrier layer 742, a storage layer 744, and a tunneling layer 746.

As shown in FIGS. 7 and 8, the TSG cuts 790 (e.g., TSG cut structures 190, 390, 380 shown in FIGS. 1-4) can vertically extend in an upper portion 828 of the stack structure 820, and laterally extend along the word line direction (X-direction). Each TSG cut 790 can partially cover the two adjacent rows of channel structures 850 in a lower portion 829 of the stack structure 820. For example, each TSG cut 790 can be located above portions of the functional layer 740, the high-K dielectric layer 730, and the channel layer 750 of the channel structures 850 in the lower portion 829 of the stack structure 820.

As shown in FIG. 7, in the lateral direction, the TSG cut 790 can being in contact with the channel layers 750 and the filling structure 760 of two adjacent rows of channel structures 850 in the upper portion 828 of the stack structure 820. That is, along the word line direction (X-direction), the TSG cut 790 can have straight sidewalls. A lateral cross section of the functional layer 740 and the channel layer 750 of the channel structure 850 in the upper portion 828 of the stack structure 820 can have a partial ring shape. Two lateral ends of the partial ring-shaped functional layer 740 and channel layer 750 can be in contact with the TSG cut 790. In some implementations, the partial ring shape is larger than a one third ring.

It is noted that, the upper portion 828 of the stack structure 820 can include any suitable number of layers of the dielectric layers 822 and the conductive layers 824. The four top pairs of the dielectric layers 822 and the conductive layers 824 shown in FIG. 8 are merely one example but not limiting the disclosed scope. In some implementations, a depth of the TSG cut 790 is greater than a total thickness of one top pair of the dielectric layers 822 and the conductive layers 824, and less than a total thickness of seven top pairs of the dielectric layers 822 and the conductive layers 824.

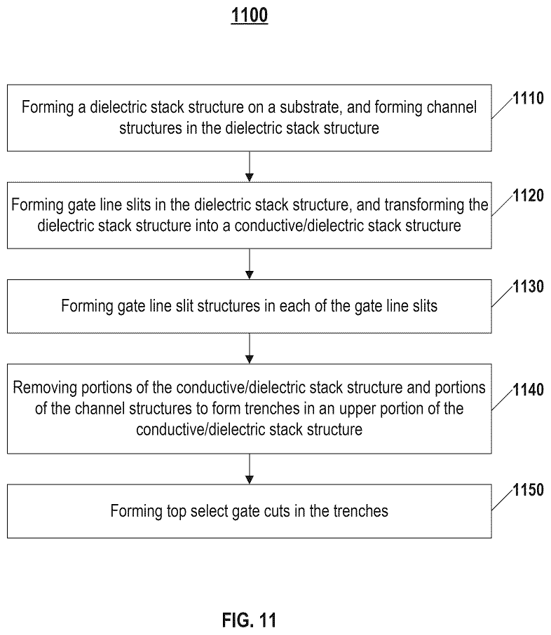

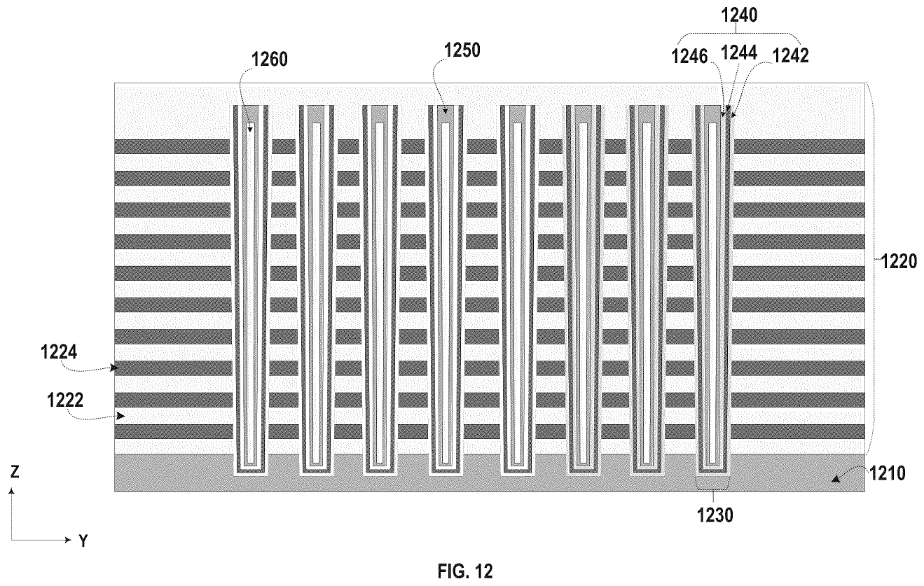

Referring to FIG. 11, a flow diagram of a method 1100 for forming a 3D memory device is shown in accordance with some implementations of the present disclosure. FIGS. 12-18 illustrate schematics of a 3D memory device at certain fabricating stages of the method 1100 shown in FIG. 11 in a cross-sectional view, according to various implementations of the present disclosure. It is understood that the operations shown in method 1100 are not exhaustive and that other operations can be performed as well before, after, or between any of the illustrated operations. Further, some of the operations may be performed simultaneously, or in a different order than shown in FIG. 11.

As shown in FIG. 11, the method can start at operation 1110, in which a dielectric stack structure can be formed on a substrate, and a plurality of channel structures can be formed in the dielectric stack structure. FIG. 4 illustrates a cross-sectional view of the 3D structure after operation 1110, according to some implementations of the present disclosure.

In some implementations, the substrate 1210 can be any suitable semiconductor substrate having any suitable structure, such as a monocrystalline single-layer substrate, a polycrystalline silicon (polysilicon) single-layer substrate, a polysilicon and metal multi-layer substrate, etc.

The dielectric stack structure 1220 including a plurality of dielectric layer pairs can be formed on the substrate 1210. The dielectric stack structure 1220 can include an alternating stack of a first dielectric layer 1222 (e.g., silicon oxide) and a second dielectric layer 1224 (e.g., silicon nitride) that is different from first dielectric layer 1222, for example. The plurality of first dielectric layers 1222 and second dielectric layers 1224 are extended in a lateral direction that is parallel to the surface of the substrate 1210. In some implementations, there are more layers than the dielectric layer pairs made of different materials and with different thicknesses in the dielectric stack structure 1220. The dielectric stack structure 1220 can be formed by one or more thin film deposition processes including, but not limited to, Chemical Vapor Deposition (CVD), Physical Vapor Deposition (PVD), Atomic Layer Deposition (ALD), or any combination thereof.

In some implementations, the dielectric stack structure 1220 can include a plurality of Silicon oxide/nitride layer pairs. Each dielectric layer pair includes a layer of silicon oxide 1222 and a layer of silicon nitride 1224. The plurality of oxide/nitride layer pairs are also referred to herein as an “alternating oxide/nitride stack.” That is, in the dielectric stack structure 1220, multiple oxide layers 1222 (shown in the areas with solid gray) and multiple nitride layers 1224 (shown in the areas with meshes) alternate in a vertical direction. In other words, except a top and a bottom layer of a given alternating oxide/nitride stack, each of the other oxide layers 1222 can be sandwiched by two adjacent nitride layers 1224, and each of the nitride layers 1224 can be sandwiched by two adjacent oxide layers 1222.

Oxide layers can each have the same thickness or have different thicknesses. For example, the thickness of each oxide layer can be in a range from 10 nm to 1210 nm, preferably about 25 nm. Similarly, nitride layers can each have the same thickness or have different thicknesses. For example, the thickness of each nitride layer can be in a range from 10 nm to 1210 nm, preferably about 35 nm.

It is noted that, in the present disclosure, the oxide layers 1222 and/or nitride layers 1224 can include any suitable oxide materials and/or nitride materials. For example, the oxide materials can include silicides, and the element of nitride materials can include, but not limited to, tungsten (W), cobalt (Co), copper (Cu), aluminum (Al), doped silicon, silicides, or any combination thereof. In some implementations, the oxide layers can be silicon oxide layers, and the nitride layers can be silicon nitride layer.

The dielectric stack structure 1220 can include any suitable number of layers of the oxide layers 1222 and the nitride layers 1224. In some implementations, the total number of layers of the oxide layers 1222 and the nitride layers 1224 in the dielectric stack structure 1220 is equal to or larger than 64. That is, a number of oxide/nitride layer pairs can be equal to or larger than 32. In some implementations, the alternating oxide/nitride stack 200 includes more oxide layers or more nitride layers with different materials and/or thicknesses than the oxide/nitride layer pair.

In some implementations, a plurality of channel structures 1230 can be formed in the dielectric stack structure 1220. Each channel structure 1230 can vertically extend through the dielectric stack structure 1220 into the substrate 1210. In some implementations, the plurality of channel structures 1230 can form an array form. In some implementations, the array of channel structures 1230 can include a plurality of rows of channel structures 1230. Each row of channel structures 1230 can be aligned along the word line direction (X-direction). Adjacent rows of channel structures 1230 can be misaligned. In some implementations, the array of channel structures 1230 can include a plurality of columns of channel structures 1230. Each column of channel structures 1230 can be aligned along the bit line direction (Y-direction). Adjacent columns of channel structures 1230 can be misaligned.

In some implementations, fabricating process for forming the multiple channel structures 1230 can include forming multiple channel holes (not shown) penetrating the dielectric stack structure 1220. A process of forming the multiple channel holes can include forming a hard mask layer (not shown) on the dielectric stack structure 1220, and coating a photoresist layer (not shown) on the hard mask layer. A pattering process can be performed to pattern the hard mask layer. Using the hard mask layer as a mask, an etching process can be followed to etch the dielectric stack structure 1220 to form the multiple channel holes. Each channel hole can completely penetrate the dielectric stack structure 1220 and extend into the substrate 1210. The etching process to form the multiple channel holes can be a dry etching, a wet etching, or a combination thereof. After the etching process, the photoresist layer and the hard mask layer can be removed.

In some implementations, a cleaning process can be performed to clean the multiple channel holes. The cleaning process can be a plasma ashing process including a high temperature ashing, and/or a wet stripping. For example, a plasma source can be used to generate a reactive species, such as oxygen or fluorine. The reactive species can combine with the photoresist remaining in the channel holes to form ash, which can be removed with a vacuum pump. Specifically, in some implementations, monatomic oxygen plasma can be created by exposing oxygen gas at a low pressure to high power radio waves, which ionize the oxygen gas. The residue of the reaction between the oxygen and photoresist material can generate ash in the plasma asher. The byproducts of the ashing process, such as volatile carbon oxides, water vapor can be pumped away with the vacuum pump within the plasma asher.

A channel structure 1230 can be formed in each channel hole in a subsequent process. The multiple channel structures 1230 can be arranged in a staggered array form. In some implementations each channel structure 1230 can include an optional high-K dielectric layer (not shown), a functional layer 1240 on the sidewall of the channel hole or covering the high-K dielectric layer, a channel layer 1250 covering the functional layer 1240, and a filling structure 1260 enclosed by the channel layer 1250. In some implementations, the functional layer 1240 can include a barrier layer 1242, a storage layer 1244, and a tunneling layer 1246.

In some implementations, fabrication processes to form the channel structures 1230 can include forming an epitaxial layer (not shown) at a bottom of each channel hole. In some implementations, the epitaxial layer can be a polycrystalline silicon (polysilicon) layer formed by using a selective epitaxial growth (SEG) process. For example, an SEG pre-clean process can be performed to clean the multiple channel holes. A following deposition process can be performed to form a polysilicon layer at the bottom of each channel hole. In some implementations, any suitable doping process, such as an ion metal plasma (IMP) process, can be performed on the polysilicon layer to form the epitaxial layer. In some implementations, the epitaxial layer may not be directly formed on the surface of the substrate 1210. One or more layers can be formed between the epitaxial layer 551 and the substrate 1210. That is, the epitaxial layer overlays the substrate 1210.

In some implementations, fabrication processes to form the channel structures 550 can include forming a high-K dielectric layer (not shown) on the sidewall of each channel hole, and forming a functional layer 1240 to cover the high-K dielectric layer. The functional layer 1240 can be a composite dielectric layer, such as a combination of a barrier layer 1242, a storage layer 1244, and a tunneling layer 1246. The high-K dielectric layer, the functional layer 1240, including the barrier layer 1242, the storage layer 1244, and the tunneling layer 1246, can be formed by one or more thin film deposition processes, such as ALD, CVD, PVD, any other suitable processes, or any combination thereof.

In some implementations, the barrier layer 1242 and/or the high-K dielectric layer can be formed between the storage layer 1244 and the sidewall of the channel hole. The barrier layer 1242 and/or the high-K dielectric layer can be used for blocking the outflow of the electronic charges. In some implementations, the barrier layer 1242 can be a silicon oxide layer or a combination of silicon oxide/silicon nitride/silicon oxide (ONO) layers. In some implementations, the high-K dielectric layer includes any suitable high dielectric constant (high k-value) dielectrics (e.g., aluminum oxide). In some implementations, the thickness of the barrier layer 1242 and/or the high-K dielectric layer can be in a range from about 3 nm to about 20 nm.

The storage layer 1244 can be formed between the tunneling layer 1246 and the barrier layer 1242. Electrons or holes from the channel layer can tunnel to the storage layer 1244 through the tunneling layer 1246. The storage layer 1244 can be used for storing electronic charges (electrons or holes) for memory operation. The storage or removal of charge in the storage layer 1244 can impact the on/off state and/or conductance of the semiconductor channel. The storage layer 1244 can include one or more films of materials including, but are not limited to, silicon nitride, silicon oxynitride, a combination of silicon oxide and silicon nitride, or any combination thereof. In some implementations, the storage layer 1244 can include a nitride layer formed by using one or more deposition processes. In some implementations, the thickness of the storage layer 1244 can be in a range from about 3 nm to about 20 nm.

The tunneling layer 1246 can be formed on the sidewall of the storage layer 1244. The tunneling layer can be used for tunneling electronic charges (electrons or holes). The tunneling layer 1246 can include dielectric materials including, but not limited to, silicon oxide, silicon nitride, silicon oxynitride, or any combination thereof. In some implementations, the tunneling layer 1246 can be an oxide layer formed by using a deposition process. In some implementations, the thickness of the tunneling layer 1246 can be in a range from about 3 nm to about 20 nm.

In some implementations, fabrication processes to form the channel structures 1230 further include forming a channel layer 1250 covering the sidewall of the functional layer 1240. In some implementations, channel layer 1250 can be an amorphous silicon layer or a polysilicon layer formed by using a thin film deposition process, such as ALD, CVD, PVD, or any other suitable process. In some implementations, the thickness of the channel layer 1250 can be in a range from about 5 nm to 20 nm.

In some implementations, fabrication processes to form the channel structures further include forming a filling structure 1260 to cover the channel layer 1250 and fill the channel hole. In some implementations, the filling structure 1260 can be an oxide layer formed by using any suitable deposition process, such as ALD, CVD, PVD, etc. In some implementations, the filling structure 1260 can include one or more airgaps (not shown).

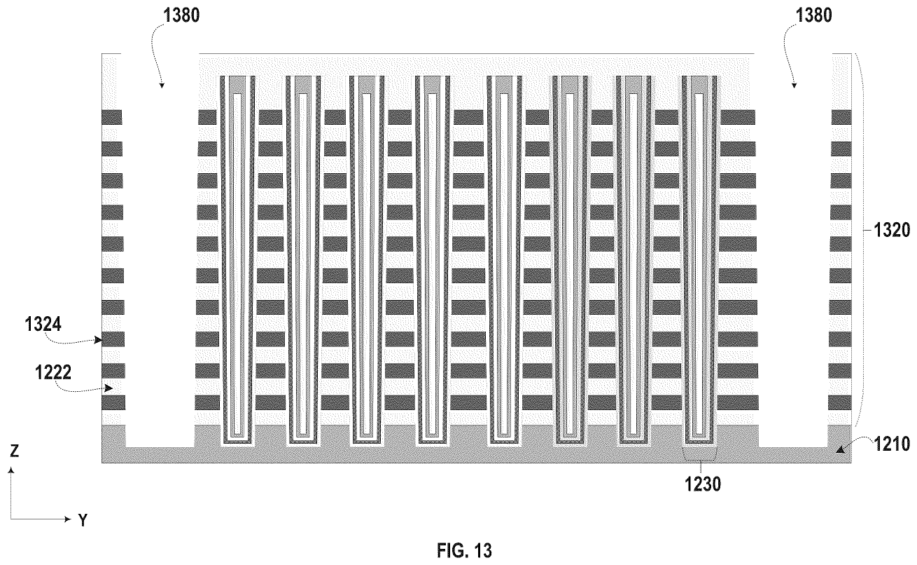

Referring back to FIG. 11, the method proceeds to operation 1120, in which multiple gate line slits (GLS) can be formed in the dielectric stack structure, and the dielectric stack structure can be transformed into a stack structure including multiple conductive/dielectric layer pairs. FIG. 13 illustrates a cross-sectional view of the 3D structure after operation 1120.

As shown in FIG. 13, the gate line slits (GLS) 1380 can each extend laterally in a straight line along the word line direction (X-direction) between two arrays of channel structures 1230, and vertically penetrate through the dielectric stack structure 1220 into the substrate 1210. The multiple GLS 1380 can be formed by forming a mask layer over the dielectric stack structure 1220 and patterning the mask using, e.g., photolithography, to form openings corresponding to the multiple GLS 1380 in the patterned mask layer. A suitable etching process, e.g., dry etch and/or wet etch, can be performed to remove portions of the dielectric stack structure 1220 exposed by the openings until the multiple GLS 1380 expose the substrate 1210. The mask layer can be removed after the formation of the multiple GLS 1380. In some implementations, a doped region (not shown) can be formed at a bottom of each GLS 1380 in the substrate 1210 by using any suitable doping process, such as ion implantation and/or thermal diffusion through the GLS 1380. The dopant in the doped region can be any suitable N+ or P+ ions. After forming a conductive wall in the GLS 1380 in a subsequent process, the lower end of each conductive wall can be in contact with a corresponding doped region.

In some implementations, a gate replacement process (also known as the “word line replacement” process) can be performed to replace second dielectric layers 1224 (e.g., silicon nitride) of the dielectric stack structure 1220 with conductive layers 1324. In some implementations, after forming the multiple GLS 1380, the second dielectric layers 1224 in the dielectric stack structure 1220 can be removed through the GLS 1380 to form multiple lateral trenches. The multiple lateral trenches can extend in a lateral direction, and can be used as spaces for conductive layers 1324 to be formed in a subsequent process. The second dielectric layers 1224 in the dielectric stack structure 1220 are used as sacrificial layers, and are removed by using any suitable etching process, e.g., an isotropic dry etch or a wet etch. The etching process can have sufficiently high etching selectivity of the material of the second dielectric layers 1224 over the materials of the first dielectric layer 1222, such that the etching process can have minimal impact on the first dielectric layer 1222. The isotropic dry etch and/or the wet etch and a following cleaning process can remove second dielectric layers 1224 in various directions to expose the top and bottom surfaces of each first dielectric layer 1222. As such, multiple lateral trenches can then be formed between first dielectric layers 1222.

As shown in FIG. 13, multiple conductive layers 1324 can be formed in the multiple lateral trenches. The multiple conductive layers 1324 can be used as word lines (i.e., gate electrodes) in the 3D memory device. In some implementations, each conductive layers 1324 can be coated with one or more insulating layers (not shown) used as gate dielectric layers for insulating the respective word line (i.e., gate electrode).

In some implementations, one or more insulating layers (not shown) can be formed in each of the multiple lateral trenches to cover the exposed surfaces of the lateral trenches with one or more suitable insulating materials. For example, one or more suitable deposition processes, such as CVD, PVD, and/or ALD, can be utilized to deposit the one or more insulating materials into the lateral trenches. In some implementations, a recess etch and/or a chemical-mechanical planarization (CMP) can be used to remove excessive insulating material(s). The one or more insulating materials can include any suitable materials (e.g., high k-value dielectrics) that provide electric insulating function. For example, the one or more insulating materials can include silicon oxide, silicon nitride, silicon oxynitride, aluminum oxide, titanium nitride, etc., and/or any suitable combinations thereof. In some implementations, multiple insulating layers can have different insulating materials.

A conductive layer 1324 can be formed in each lateral trench between the one or more insulating layers. The conductive layer 1324 can be formed by filling the lateral trenches with a suitable gate electrode metal material. The conductive layer 1324 can provide the base material for the subsequently-formed word lines (i.e., gate electrodes). The gate electrode metal material can include any suitable conductive material, e.g., tungsten, aluminum, copper, cobalt, or any combination thereof, for forming the word lines (i.e., gate electrodes). The gate electrode material can be deposited into lateral trenches using a suitable deposition method such as CVD, physical vapor deposition (PVD), plasma-enhanced CVD (PECVD), sputtering, metal-organic chemical vapor deposition (MOCVD), and/or ALD. In some implementations, the conductive layers 1324 include tungsten formed by CVD. As such, the dielectric stack structure 1220 is transformed into a stack structure 1320 including alternating conductive/dielectric layers.

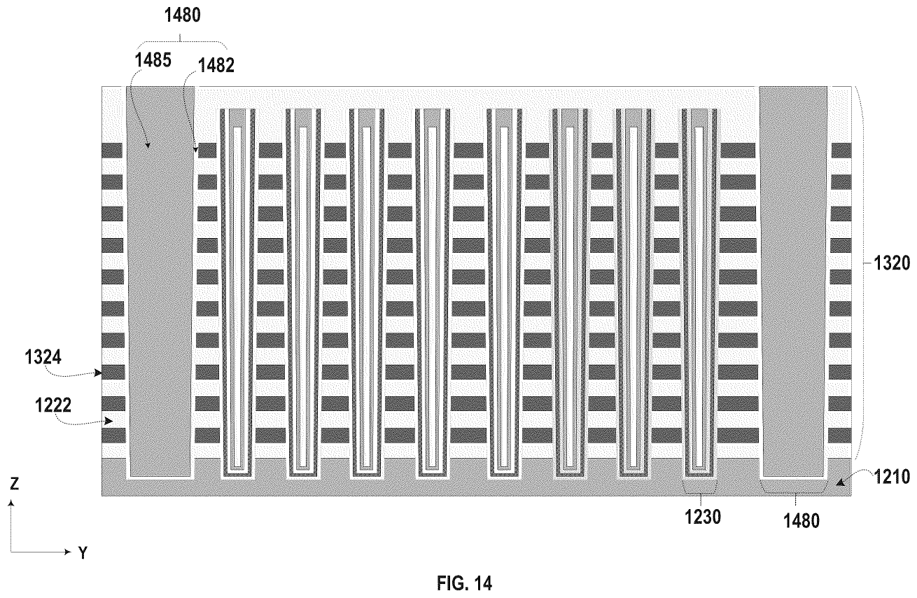

Referring back to FIG. 11, the method proceeds to operation 1130, in which a gate line slit (GLS) structure can be formed in each GLS. FIG. 14 illustrates a cross-sectional view of the 3D structure after operation 1130.

In some implementations, the fabricating process for forming the GLS structure 1480 can include forming a spacer layer 1482 on the sidewalls of the multiple GLS 1380. The spacer layer 1482 is also referred as a gate line spacer (GLSP) layer, and can be used to provide electrical insulation between the multiple conductive layers 1324 and a conductive wall formed in a subsequent process.

In some implementations, the fabricating process for forming spacer layer 1482 can include a word line gate recess process. After forming the multiple conductive layers 1324, portions of the multiple conductive layers 1324 (word lines) exposed by the GLS 1380 can be removed by a recess etching process. In some implementations, in order to ensure the insulation between multiple conductive layers 1324 (word lines), a recess etching process, such as a wet etching process, can be performed to remove portions of the multiple conductive layers 1324 exposed by the GLS 1380. In doing so, a recess can be formed in each lateral trench adjacent to the GLS 1380.

In some implementations, the spacer layer 1482 can have a laminated structure (not shown) including two or more spacer sublayers formed by using any suitable deposition processes, such as atomic layer deposition (ALD) processes. For example, the spacer layer 1482 can include a first spacer sublayer (not shown) covering the sidewall of the GLS 1380 and the exposed surfaces of the multiple gate structures. The first spacer sublayer can include a low temperature oxide material, such as silicon oxide, configured to prevent the multiple conductive layers 1324 from being oxidized in the subsequent processes. The spacer layer 1482 can further include a second spacer sublayer (not shown) to cover the first spacer sublayer. The second spacer sublayer can include a high k-value material, such as silicon nitride. Such laminated structure can efficiently increase the equivalent oxide thickness (EOT) of the spacer layer 1482, thereby improving the isolation performance of the spacer layer 1482.

In some implementations, the fabricating process for forming the GLS structure 1480 can include forming a conductive wall 1845 in each GLS. The conductive wall 1845 can be in contact with the doped region (not shown) in the substrate 1210, and is used as an array common source (ACS) of the multiple NAND strings. In some implementations, the conductive wall 1845 can be formed by depositing a conductive material, such as polysilicon, silicides, tungsten, aluminum, copper, and/or combinations thereof, etc. The conductive material can be deposited into the multiple GLS 1380 using a suitable deposition method such as CVD, physical vapor deposition (PVD), plasma-enhanced CVD (PECVD), sputtering, metal-organic chemical vapor deposition (MOCVD), and/or ALD. A following a chemical-mechanical planarization (CMP) process can be performed to planarize the top surface of the formed 3D structure.

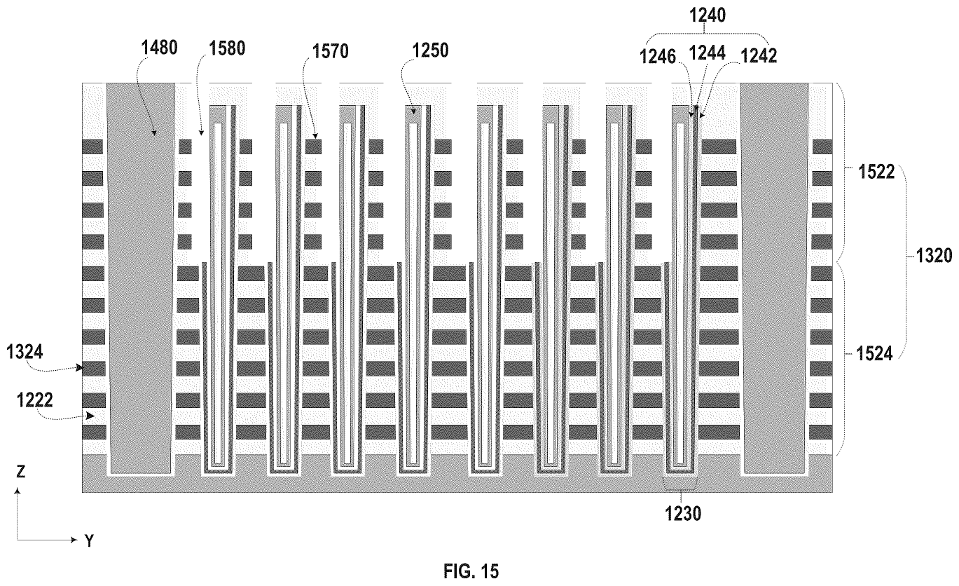

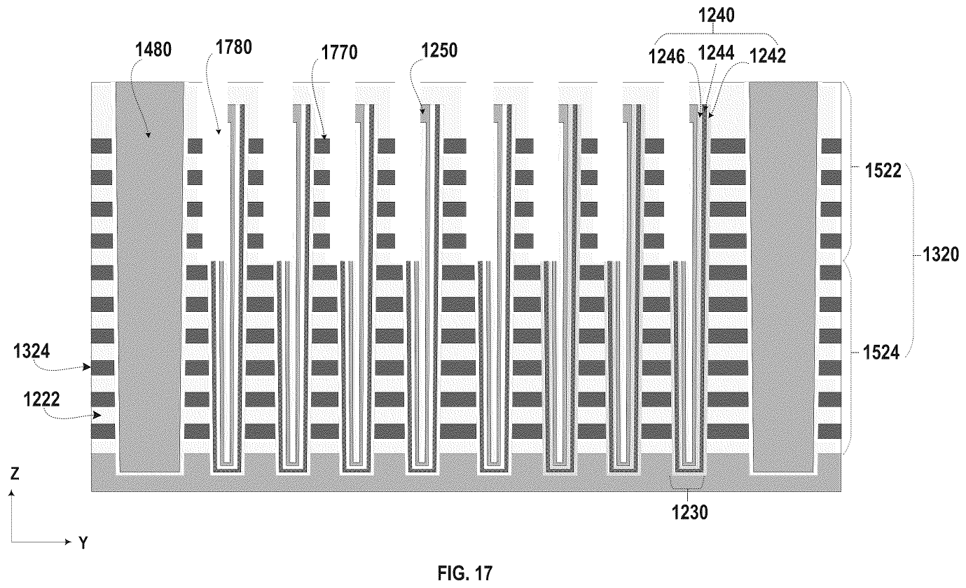

Referring back to FIG. 11, the method proceeds to operation 1140, in which portions of the stack structure and portions of the channel structures in an upper portion of the stack structure can be removed to form a plurality of trenches. FIG. 15 illustrates a cross-sectional view of the 3D structure after operation 1140, according to some implementations of the present discourse. FIG. 17 illustrates a cross-sectional view of the 3D structure after operation 1140, according to some other implementations of the present discourse.

As shown in FIGS. 15 and 17, the trenches 1580/1780 can each extend laterally along the word line direction (X-direction). In some implementations, trenches 1580/1780 can be used to form the TSG cuts 190 as shown in FIG. 1 in a subsequent process. In such implementations, the trenches 1580/1780 can be formed between adjacent rows of channel structures 1230. The plurality of trenches 1580/1780 can laterally extend in parallel along the word line direction (i.e., X-direction) and vertically extend in an upper portion 1522 of the stack structure 1320. Each trench 1580/1780 can expose the channel layers 1250 of two adjacent rows of channel structures 1230. The conductive layers 1324 in the upper portion 1522 of the stack structure 1320 can be divided by the trenches 1580/1780 into a plurality of sub-blocks 1570/1770. That is, two adjacent rows of channel structures 1230 between two adjacent trenches 1580/1780 can share one sub-block 1570/1770. In some implementations, the first number of the trenches 1580/1780 between adjacent gate line structures 1480 plus one is a half of a second number of the rows of channel structures 1230 between the adjacent gate line structure 1480.

In some other implementations, trenches 1580/1780 can be used to form the first TSG cuts 390 and second TSG cuts 380 as shown in FIG. 3 in a subsequent process. In such implementations, the trenches 1580/1780 can be formed to include a plurality of first trenches and second trenches alternatively arranged along the bit line direction (i.e., Y-direction). The plurality of first trenches and second trenches can laterally extend in parallel along the word line direction (i.e., X-direction) and vertically extend in an upper portion 1522 of the stack structure 1320. Each second trenches can include a plurality of second trench segments discontinuously extended along the word line direction (X-direction). Each first trenches or second trenches can expose the channel layers 1250 of two adjacent rows of channel structures 1230. It is noted that, the channel structures located at the corners of the second trench segments can be used as the dummy channel structures. The conductive layers 1324 in the upper portion 1522 of the stack structure 1320 can be divided by the first trenches into a plurality of sub-blocks 1570/1770, while the discontinuous second trench segments do not separate the conductive layers 1324. That is, four adjacent rows of channel structures 1230 between two adjacent first trenches can share one sub-block 1570/1770.

A suitable etching process, e.g., dry etch and/or wet etch, can be performed to remove portions of the stack structure 1320 and portions of the channel structures 1230 to form trenches 1580/1780. In some implementations, the trenches can extend and penetrate top one to seven oxide/nitride layer pairs of the stack structure 1320. A mask layer (not show) can be used to control the shape of the trenches 1580/1780 during the etching process. In some implementations as shown in FIG. 15, the channel layers 1250 of the channel structure 1230 are not removed during the etching process. As such, the formed tranches 1580/1780 can have concave sidewalls, and can be used to form GLS cuts 590 as shown in FIG. 5. In some other implementations as shown in FIG. 17, portions of the channel layers 1250 of the channel structure 1230 can be also removed during the etching process. As such, the formed tranches 1580/1780 can have substantial straight sidewalls, and can be used to form GLS cuts 790 as shown in FIG. 7. The mask layer can be removed after the formation of the trenches 1580/1780.

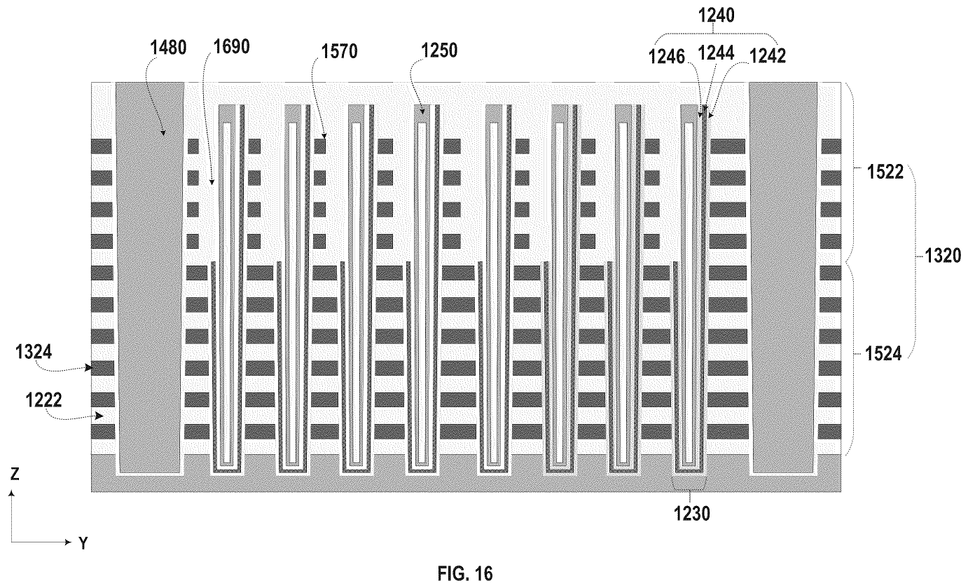

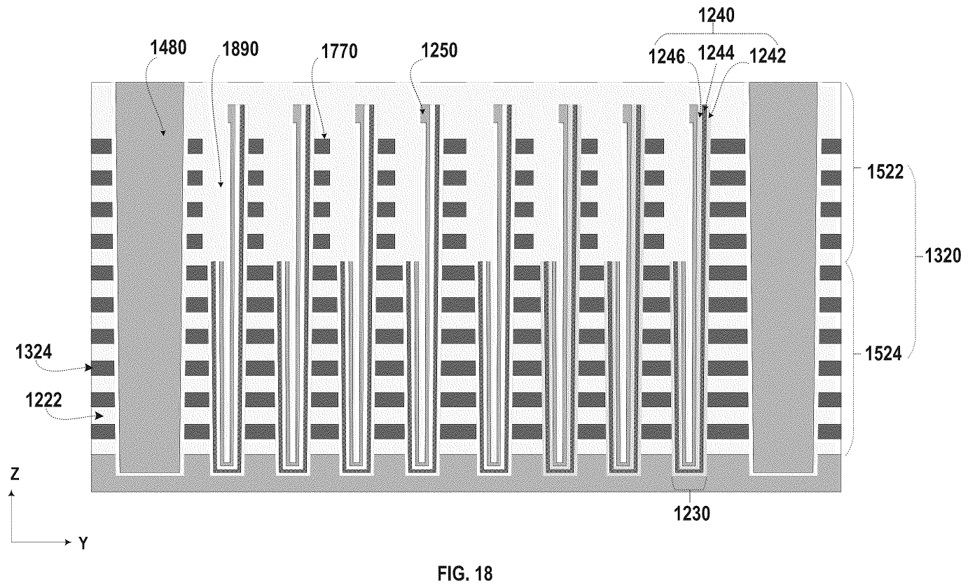

Referring back to FIG. 11, the method proceeds to operation 1150, in which TSG cuts can be formed in the plurality of trenches. FIG. 16 illustrates a cross-sectional view of the 3D structure after operation 1150, according to some implementations of the present discourse. FIG. 18 illustrates a cross-sectional view of the 3D structure after operation 1150, according to some other implementations of the present discourse.

As shown in FIGS. 16 and 18, in some implementations, a deposition process can then be performed to fill the trenches 1580/1780 with any suitable filling material (e.g., silicon oxide) to form the TSG cuts 1690/1890. It is noted that, the formed TSG cuts 1690/1890 can be either TSG cuts 190 as shown in FIG. 1 or TSG cuts 380/390 as shown in FIG. 3. The detailed features of TSG cuts 1690/1890 can be referred to the descriptions above in connection with FIGS. 1 and 3. It is also noted that, the formed TSG cuts 1690 can be the TSG cuts 590 as described above in connection with FIGS. 5-6, and the formed TSG cuts 1890 can be the TSG cuts 790 as described above in connection with FIGS. 7-8.

Accordingly, 3D memory devices and fabricating methods are provided. In some implementations of the disclosed 3D memory devices, two rows of channel structures can be used as a group. As such, the bit line connection does not require a double pattern but can be realized by a single patten. That is, one layer of TSG structure plus one bit line can control a single row of channel structure, thereby reducing disturbance during programming and reading and reducing metal wiring. Further, in some implementations of the disclosed 3D memory devices, the channel structures corresponding to TSG structures can be designed to have a partial circular shape. That is, the current switch of the channel structure can be controlled through a partial-circular gate electrode of the TSG. As such, there is no need to design a partition area as the dummy channel structures. The disclosed design of TSG isolation function can be fabricated by simple processes without increasing process costs and/or produce area.

The foregoing description of the specific implementations will so fully reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A semiconductor structure, comprising:
a stack structure including a plurality of dielectric layers and conductive layers alternatively stacked in a vertical direction;
an array of channel structures each vertically penetrating the stack structure, each channel structure including a functional layer and a channel layer; and
a plurality of isolation structures extending in parallel along a first lateral direction and vertically in an upper portion of the stack structure, each isolation structure being in contact with the channel layers of two adjacent rows of channel structures.

2. The semiconductor structure of claim 1, wherein:
each isolation structure partially covers the two adjacent rows of channel structures in a lower portion of the stack structure.

3. The semiconductor structure of claim 2, wherein the plurality of isolation structures comprises:
a plurality of first isolation structures each separating the conductive layers of the upper portion of the stack structure into sub-blocks.

4. The semiconductor structure of claim 1, wherein the isolation structure is in contact with curved side surfaces of the channel layers of the two adjacent rows of channel structures in the upper portion of the stack structure.

5. The semiconductor structure of claim 1, wherein the isolation structure is in contact with filling structures of the two adjacent rows of channel structures in the upper portion of the stack structure.

6. The semiconductor structure of claim 3, wherein a column of channel structures extending along a second lateral direction and located on a same side of the first isolation structures are connected to a common bit line.

7. The semiconductor structure of claim 3, wherein the plurality of isolation structures further comprises:
a plurality of second isolation structures each extending along the first lateral direction without separating the conductive layers of the upper portion of the stack structure,
wherein the plurality of first and second isolation structures are alternatively arranged along a second lateral direction.

8. The semiconductor structure of claim 7, wherein the plurality of second isolation structures each including a plurality of second isolation segments discontinuously extended along the first lateral direction.

9. The semiconductor structure of claim 7, wherein:
a first subset of a column of channel structures extending along a second lateral direction and in contact with the first isolation structures are connected to a first common bit line; and
a second subset of the column of channel structures in contact with the second isolation structures are connected to a second common bit line.

10. The semiconductor structure of claim 8, wherein the array of channel structures comprises dummy channel structures in contact with corners of the second isolation segments.

11. The semiconductor structure of claim 1, further comprising:
a plurality of gate line structures extending in parallel along the first lateral direction and vertically penetrating the stack structure,
wherein a first number of the isolation structures between adjacent gate line structures plus one is a half of a second number of the rows of channel structures between the adjacent gate line structure.

12. The semiconductor structure of claim 1, wherein:
a lateral cross section of the functional layer of the channel structure in the upper portion of the stack structure has a partial ring shape; and
two lateral ends of the partial ring-shaped functional layer are in contact with the isolation structure.

13. The semiconductor structure of claim 5, wherein:
a lateral cross section of the channel layer of the channel structure in the upper portion of the stack structure has a partial ring shape; and
two lateral ends of the partial ring-shaped channel layer are in contact with the isolation structure.

14. The semiconductor structure of claim 12, wherein the partial ring shape is larger than a one third ring.

15. The semiconductor structure of claim 1, wherein a depth of the isolation structure is greater than a total thickness of one top pair of the dielectric layers and the conductive layers, and less than a total thickness of seven top pairs of the dielectric layers and the conductive layers.

16. A semiconductor device, comprising:
a plurality of isolation structures extending in parallel along a first lateral direction and vertically in an upper portion of a stack structure; and
an array of channel structures each vertically penetrating the stack structure and comprising:
a lower channel portion having a cylinder shape in a lower portion of the stack structure, and
an upper channel portion having a partial cylinder shape in the upper portion of the stack structure and being in contact with a corresponding isolation structure.

17. The semiconductor device of claim 16, wherein each isolation structure partially covers the two adjacent rows of channel structures in a lower portion of the stack structure.

18. The semiconductor device of claim 16, wherein the plurality of isolation structures comprises:
a plurality of first isolation structures each separating the conductive layers of the upper portion of the stack structure into sub-blocks;
a plurality of second isolation structures each including a plurality of second isolation segments discontinuously extended along the first lateral direction; and
the plurality of first and second isolation structures are alternatively arranged along a second lateral direction.

19. The semiconductor device of claim 16, wherein the isolation structure is in contact with curved side surfaces of the channel layers of the two adjacent rows of channel structures in the upper portion of the stack structure.

20. The semiconductor device of claim 16, wherein the isolation structure is in contact with filling structures of the two adjacent rows of channel structures in the upper portion of the stack structure.
